(19) United States
(12) Patent Application Publication
(10) Pub. No.: US 2008/0180182 A1
(43) Pub. Date: Jul. 31, 2008

(54) Delay unit

(76) Inventors: Yen-An Chang, Hsinchu (TW); Ming-Fou Lee, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/657,623

(22) Filed: Jan. 25, 2007

(51) Int. Cl. H03H 11/26; H03K 3/03

(52) U.S. Cl. 331/57

(57) ABSTRACT

The present invention is related to a delay unit, and more particularly to a delay unit with respect to delay an input signal. The delay unit comprises a ring oscillator and a counter. The ring oscillator receives an input signal and generates a clock signal. The counter connects to the ring oscillator for receiving the clock signal and generating a delay signal. The delay signal feeds back to the ring oscillator to stop the ring oscillator, and the power consumed in the delay unit can be reduced. The ring oscillator comprises a plurality of inverters and the counter comprises a plurality of flip-flops, and the delay unit can generate an accurately and/or large delay time by changing the number of the inverters and/or the flip-flops.

### FIELD OF THE INVENTION

The present invention relates to a delay unit, and more particularly to a delay unit for delaying an input signal.

### BACKGROUND

FIG. 1 is a circuit diagram of a conventional delay unit. The delay unit 10 comprises a plurality of MOS (P1, P2, N1, N2), a capacitor C and a resistor R. The delay unit 10 receives an input signal 15 and outputs an output signal 19 in response. The output signal 19 is a delay signal with respect to the input signal 15, and a delay time Td is detected between the input signal 15 and the output signal 19.

In this conventional delay unit 10, people change the capacitance of the capacitor C, the resistance of the resistor R or the W/L Ratio of the MOS transistors (P1, P2, N1, N2) to change the value of the delay time Td. For example, we can change the value of the delay time Td according to the requirement of an IC circuit. If the value of the delay time Td generated by delay unit 10 is not too large, for example, in the scale of nano-second, the area of the delay unit 10 will be acceptable, and the value of delay time Td can be controlled easily.

If a larger delay time Td is required for the IC circuit, we can increase the capacitance and resistance of the capacitor C and resister R of the delay unit 10 to generate a larger delay time. But it is very difficult to generate an accurate delay time Td for the delay unit 10 by adjusting the capacitance and resistance of the capacitor C and resister R.

Besides, as the capacitance and resistance of the capacitor C and resister R increase, the area of the delay unit 10 increases, too. If a large delay time is required, it costs a large area delay unit 10. A large area delay unit 10 is not beneficial for the circuit integration, and much expensive for the layout of the IC circuit.

### SUMMARY OF THE INVENTION

According to the problems encountered by the above mentioned prior art, a novel delay unit is provided for reducing the area of delay unit and controlling the delay time accurately, which is the key point of the present invention.

It is a primary object of the present invention to provide a delay unit, comprising a ring oscillator and a counter. When a delay signal is generated from the counter, it feeds back to the ring oscillator and stops the ring oscillator. Thus the power consumption of the delay unit is reduced.

It is a secondary object of the present invention to provide a delay unit with a counter comprising at least one flip-flop. The value of the delay time is controlled accurately according to the number of the flip-flops in the counter. It is easy for the delay unit of the present invention to generate an accurate delay time.

It is another object of the present invention to provide a delay unit without large capacitor and large resistor, so that the area of delay unit can be reduced.

It is another object of the present invention to provide a delay unit which generates a large delay time with a small area.

It is another object of the present invention to provide a delay unit which can provide wide range delay times accurately from the scale of nano-second order to second order by changing the cycle time of the ring oscillator.

It is another object of the present invention to provide a delay unit, comprising a ring oscillator, a counter, and a phase selector. It is easy for the delay unit of the present invention to generate various delay times.

To achieve the above mentioned objects, the present invention provides a delay unit, comprising: an oscillator for receiving an input signal and generating a clock signal; and a counter connected to the oscillator for receiving the clock signal, generating a delay signal, and feeding back the delay signal to the oscillator.

### BRIEF DESCRIPTION OF DRAWINGS

FIG. 1 is a circuit diagram of a conventional delay unit.

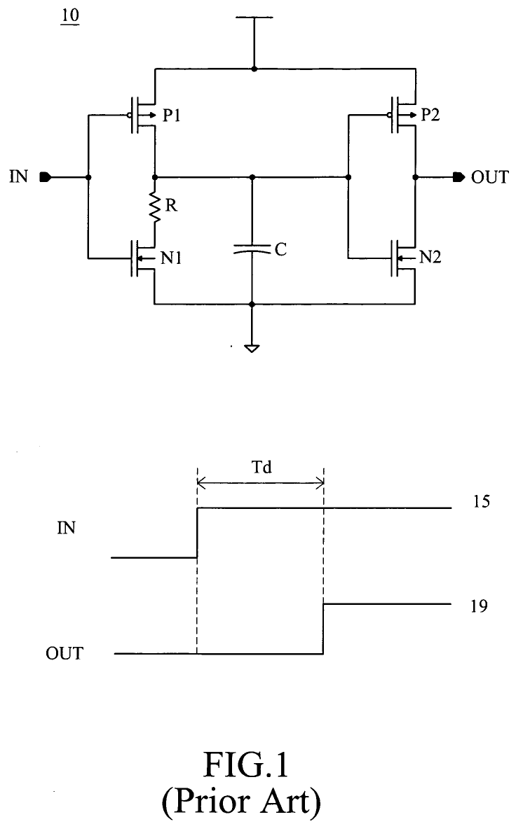

FIG. 2 is a block diagram of an embodiment of the present invention.

FIG. 3 is a flow chart of the present invention.

FIG. 4 is a circuit diagram of one embodiment of the present invention.

FIG. 5 is a circuit diagram of another embodiment of the ring oscillator of the present invention.

FIG. 6 is a circuit diagram of another embodiment of the ring oscillator of the present invention.

FIG. 7 is a bock diagram of another embodiment of the present invention.

FIG. 8 is a circuit diagram of another embodiment of the present invention.

### DETAILED DESCRIPTION

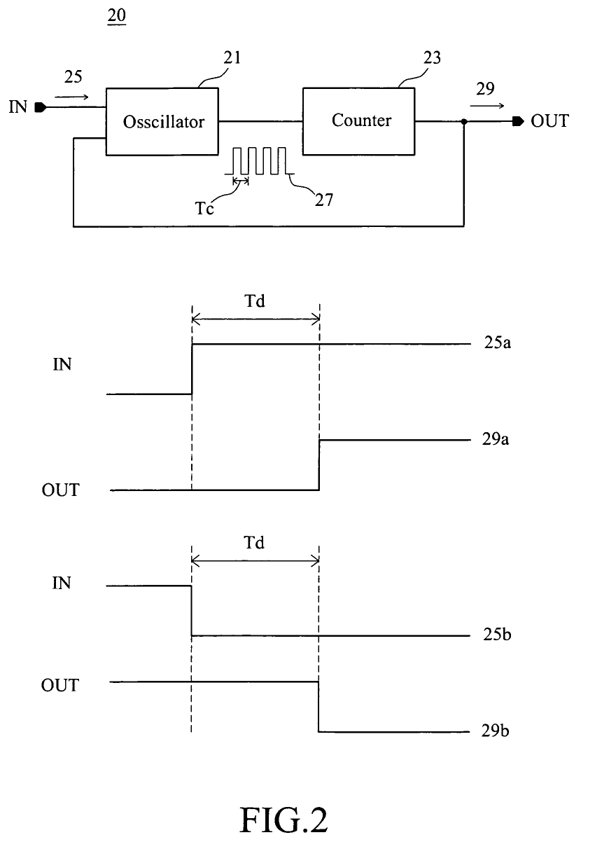

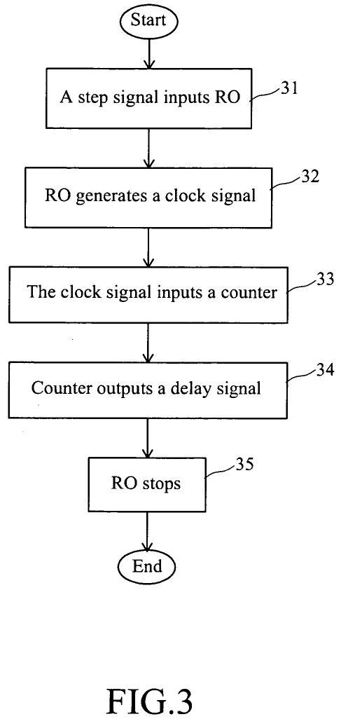

Referring to FIG. 2 and FIG. 3, there are shown a block diagram and a flow chart of one embodiment of the present invention respectively. The delay unit 20 comprises an oscillator 21 and a counter 23. The oscillator 21 receives an input signal 25 and generates a clock signal 27. The counter 23 is connected to the oscillator 21 for receiving the clock signal 27. It generates a delay signal 29 in response to the clock signal 27 and feeds the delay signal 29 back to the oscillator 21 to stop the oscillator 21.

The input signal 25 can be a step signal, for example, a step signal 25a from low to high or a step signal 25b from high to low as shown in FIG. 2. When the oscillator 21 receives the input signal 25, as the step 31 shown in FIG. 3, it oscillates and generates a clock signal 27, as the step 32. The clock signal 27 generated by oscillator 21 inputs to the counter 23, as the step 33, and the counter 23 will output the delay signal 29 after a predetermined delay time Td, as the step 34.

The delay signal 29 is fed back to the oscillator 25, and the oscillator 25 stops oscillating immediately in response to the feed back signal, as the step 35. By using the technic of the present invention, the delay time Td between the input signal 25 and the delay signal 29 can be determined accurately.

By means of stopping the oscillator 21 after the delay signal 29 outputted, the power consumption of the delay unit 20 is reduced, and the power consumption of the system is reduced, too. The oscillator 21 will keep in a stopped state, until the oscillator 21 receives another input signal. The oscillator 21 will oscillate and generate another clock signal, when it receives another input signal.

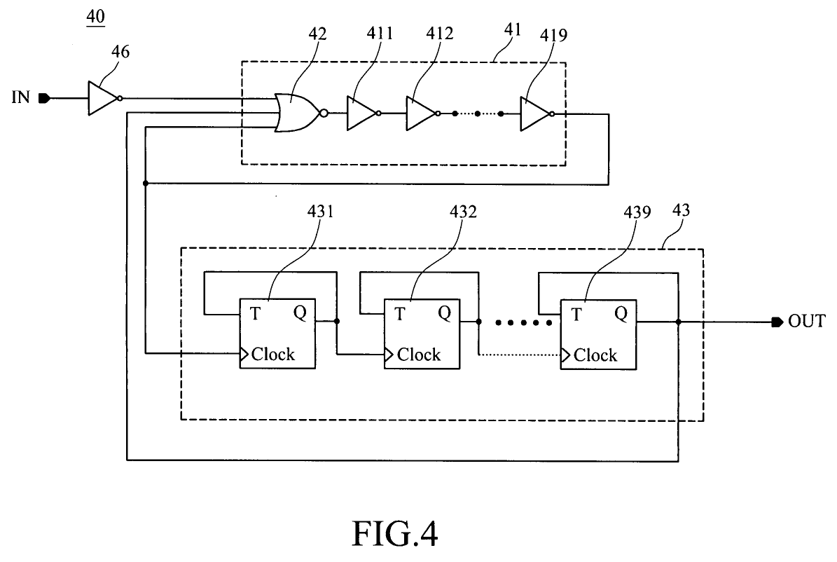

Referring to FIG. 4, there is shown a circuit diagram of one embodiment of the present invention. In this embodiment, the delay unit 40 comprises a ring oscillator 41 and a counter 43. The ring oscillator 41 comprises at least one inverter, such as 411, 412, . . . , and 419. The counter 43 comprises at least one flip-flop, such as 431, 432, . . . , and 439. The ring oscillator 41 further comprises a logic gate connected to the inverters for receiving the input signal 25 and the delay signal 29 from the counter 43. The number of the inverters in the ring oscillator 41 can be an odd number or an even number. For example, if the number of the inverters in the ring oscillator 41 is an even number, the logic gate should be a NOR gate 42 connected to the inverter 411. If the number of the inverters in the ring oscillator 41 is an odd number, the logic gate should be an OR gate connected to the inverter 411.

When the counter 43 outputs the delay signal 29, and feeds it back to the logic gate 42 of the ring oscillator 41, the logic gate 42 will stop the ring oscillator 41.

The value of the delay time Td can be changed by the counter 43, for example, we can control the value of delay time Td by changing the number of flip-flop of the counter 43. According to the technic of the present invention, the delay unit 40 can produce an accurate delay time Td in a slight area.

We can also adjust the value of the delay time Td by changing the value of the cycle time Tc of clock signal 27 generated from the ring oscillator 41. The range of the delay time Td can be provided accurately from the scale of nano-second order to second order by changing the number of flip-flop and the cycle time Tc of the clock signal 27. The value of the delay time Td generated by the delay unit 20/40 of the present invention is more accurate and various than the delay time Td generated by the prior art.

In the present embodiment, the cycle time Tc of the clock signal 27 outputted from the ring oscillator 41 increases, when the number of inverters of the ring oscillator 41 increases. The relationship between the cycle time Tc and the delay time Td is Td=2⁽ⁿ⁻¹⁾T_{c}, wherein n is the number of the flip-flops in the counter 43. The delay time Td will increase, when the number of the flip-flop increases. For example, the cycle time Tc of the clock signal 27 is t, and the number of flip-flops in the counter 43 is 3, and than the delay time Td will be 4 times of t.

People can add an inverter 46 connected to the ring oscillator 41 for changing the input signal 25. For example, if the input signal 25 is a step signal from low to high, it will be transformed into a step signal from high to low by the inverter 46 for suitable use in the delay unit 40. The delay unit 40 without adding an inverter 46 connected to the ring oscillator 41 if the input signal 25 is a step signal from high to low.

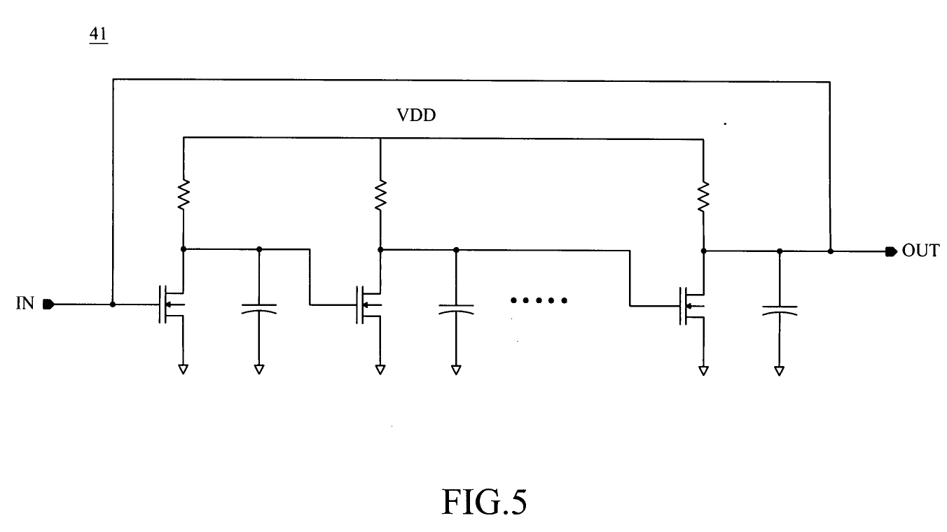

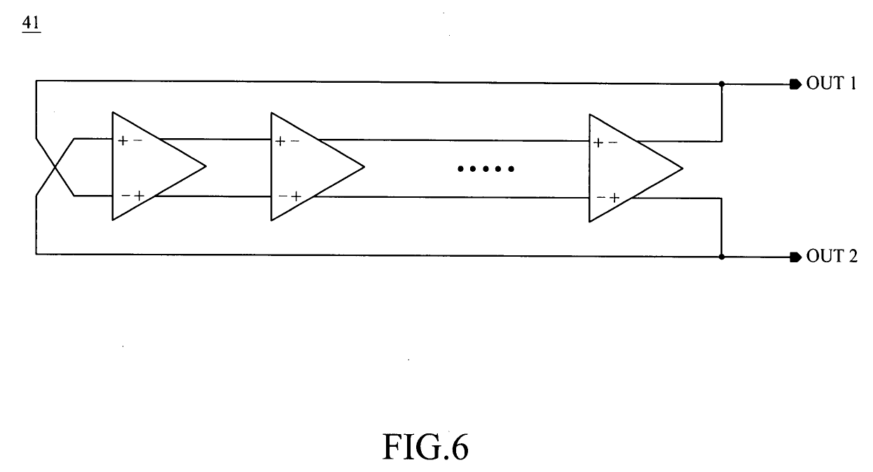

Referring to FIG. 5 and FIG. 6, there are shown the circuit diagram of another embodiments of the ring oscillator of the present invention respectively. In the embodiments, the ring oscillator 41 comprises at least one amplifier. The amplifier can be a common source amplifier as shown in FIG. 5 or a differential amplifier as shown in FIG. 6. In FIG. 5, the number of the amplifiers must be odd. In FIG. 6, the number of the amplifiers can also be odd or even. The ring oscillator 41 receives an input signal 25, and generates a clock signal 27. The ring oscillator 41 also comprises a logic gate 42 for receiving the delay signal 29 outputted from the counter 43. When the logic gate 42 receives the delay signal 29, the logic gate 42 will stop the ring oscillator 41.

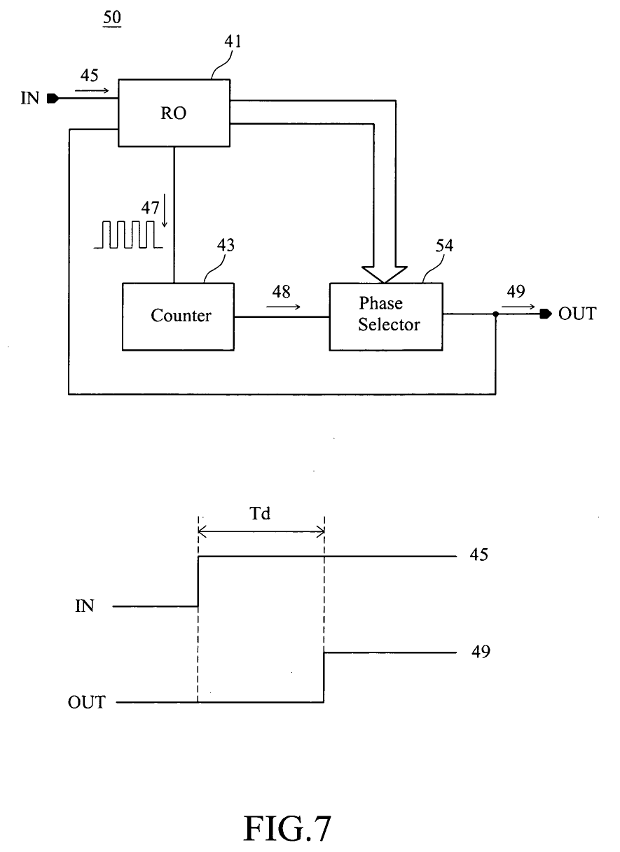

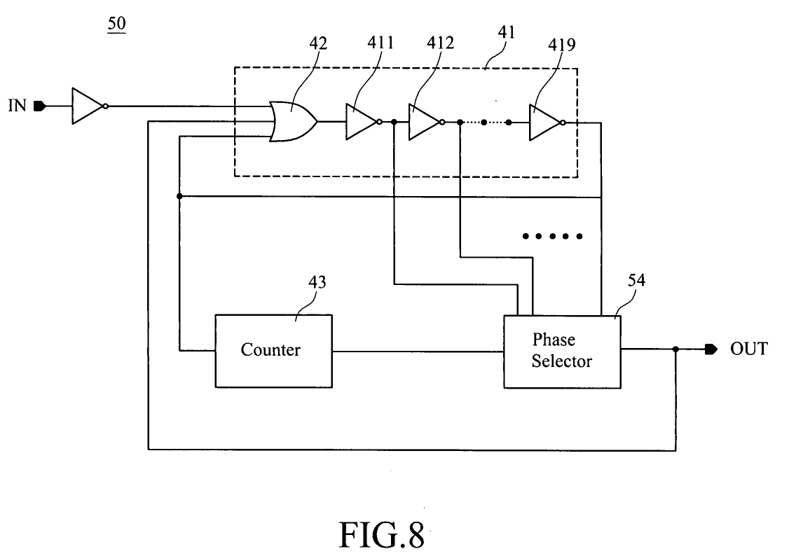

Referring to FIG. 7 and FIG. 8, there are shown the block diagram and circuit diagram of another embodiment of the present invention respectively. The delay unit 50 comprises a ring oscillator 41, a counter 43 and a phase selector 54. The counter 43 is connected to the ring oscillator 41 for receiving the clock signal 47. The phase selector 54 is connected to the ring oscillator 41 and the counter 43 for generating the delay signal 49. The delay signal 49 is fed back to the ring oscillator 41 and stops the ring oscillator 41.

The ring oscillator 41 comprises at least one inverter, such as 411, 412, . . . , and 419, and a logic gate 42. The counter 43 can be a divider comprising at least one flip-flop. The phase selector 54 connects to the counter 43 for receiving the output signal 48 generated by the counter 43, and connects to the output of each inverter of ring oscillator 41 for receiving the signal generated from one of the inverters.

The delay time between the output signal 48 generated from the counter 43 and the input signal 45 is an integer multiple of the cycle time Tc of clock signal 47. The phase selector 54 is enabled by the output signal 48, and then chooses the signal generated from one of the inverters of the ring oscillator 41, and output the chosen signal as the delay signal 49. The delay time Td between the input signal 45 and the delay signal 49 becomes an integer multiple and a fraction of the cycle time Tc of the clock signal 47.

For example, if the cycle time of clock signal is Tc, and the number of flip-flops of the counter 43 is n, and the number of inverters of the ring oscillator 41 is m, and the phase selector 54 selects the output signal of the x^{th} inverter, the relationship between the cycle time Tc and the delay time Td is T_{d}=(2⁽ⁿ⁻¹⁾+x/m)T_{c}.

The present invention is not limited to the above-described embodiments. Various alternatives, modifications and equivalents may be used. Therefore, the above embodiments should not be taken as limiting the scope of the invention, which is defined by the appending claims.

1. A delay unit, comprising:
an oscillator for receiving an input signal and generating a clock signal; and
a counter connected to said oscillator for receiving said clock signal, generating a delay signal, and feeding back said delay signal to said oscillator.

2. The delay unit of claim 1, wherein said oscillator is a ring oscillator.

3. The delay unit of claim 2, wherein said ring oscillator comprises at least one inverter.

4. The delay unit of claim 3, wherein the number of said inverters is an odd number.

5. The delay unit of claim 2, wherein said ring oscillator comprises at least one amplifier.

6. The delay unit of claim 5, wherein the number of said amplifiers is one of odd number or even number.

7. The delay unit of claim 5, wherein said amplifier is one of a common source amplifier or a differential amplifier.

8. The delay unit of claim 2, wherein said ring oscillator comprises:
a logic gate for receiving said input signal and said delay signal from said counter; and
an even number of inverters connected to said logic gate in series for generating said clock signal.

9. The delay unit of claim 8, wherein said logic gate is a NOR gate.

10. The delay unit of claim 2, wherein said counter comprises at least one flip-flop.

11. The delay unit of claim 2, wherein said counter is a divider.

12. The delay unit of claim 2, further comprising a phase selector connected to said counter and said ring oscillator.

13. The delay unit of claim 12, wherein said ring oscillator comprises at least one inverter, and said phase selector is connected to the output of each said inverter.

14. The delay unit of claim 2, further comprising an inverter connected to said ring oscillator for receiving said input signal.
